(19) United States
(12) Patent Application Publication
(10) Pub. No.: US 2008/0094268 A1
(43) Pub. Date: Apr. 24, 2008

(54) Ad Converter Arrangement

(75) Inventors: Marcel Pelgrom, Eindhoven (NL); Kathleen Philips, Eindhoven (NL); Petrus Antonius Cornelis Maria Nuijten, Eindhoven (NL); Raf Lodewijk Jan Roovers, Eindhoven (NL); Lucien Johannes Breems, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics, N.V., Eindhoven (NL)

(21) Appl. No.: 11/815,980

(22) PCT Filed: Feb. 13, 2006
(86) PCT No.: PCT/IB06/50463

§ 371 Date: Aug. 10, 2007

(30) Foreign Application Priority Data
Feb. 15, 2005 (EP) 05101118.7

(51) Int. Cl. H03M 1/12

(52) U.S. Cl. 341/155

(57) ABSTRACT

In an AD converter a primary ΣA-modulator digitizes the analog input signal. The quantization noise generated thereby is isolated in the analog domain and digitized in a secondary ΣA-modulator. The quantization noise so digitized by the secondary ΣA-modulator is subtracted from the quantization noise in the output of the primary ΣA-modulator. Because the quantization noise generated by the primary ΣA-modulator is subject to filtering (shaping) the quantization noise digitized in the secondary ΣA-modulator should also be filtered. This is performed by similar filtering in the feedback path of the secondary ΣA-modulator.

The invention relates to an AD converter arrangement comprising a primary and a secondary ΣA-modulator each with an input terminal for receiving an analog input signal, filtering means in a forward path between said input terminal and a quantizer, an output terminal connected to the output of the quantizer and a feedback path connected from the output of the quantizer to the filtering means, the AD converter arrangement further comprising means to apply an analog input signal to the input terminal of the primary ΣA-modulator, means to isolate the quantization noise generated in the primary ΣA-modulator, means to apply said isolated quantization noise to the input terminal of the secondary ΣA-modulator and means to derive a combination of the digital output signals of the two ΣA-modulators so as to substantially reduce the quantization noise of the primary ΣA-modulator in said combination. Such AD-converter arrangement is known from the article “A Cascaded Continuous-time ΣA-modulator with 67 dB Dynamic Range in 10 MHz Bandwidth” in 2004 IEEE International Solid-State Circuits Conference/Session 4/Oversampled ADC's/4.1.

Presently the ΣA-modulator has become a leading principle in analog-to-digital (AD) conversion. In ΣA-modulators the order of the filter in the converter determines to a large extend its quality (expressed as signal-to-noise ratio). At higher orders the shaping of the quantization noise to higher frequencies and therewith the suppression of the noise in the base-band becomes better and consequently the signal to noise ratio and the dynamic range improve. However the higher order of the filter causes the loop of the ΣA-modulator to become potentially unstable. Instability becomes significant at high input voltage excursions. A solution to this problem is found in the so-called cascaded ΣA-modulator. Two ΣA-modulators are now employed: the primary ΣA-modulator has a relatively low order so that the stability is not in danger at the cost of higher quantization noise in the frequency band of the input signal. By means of a subtraction point this quantization noise is fed in analog form to the secondary ΣA-modulator, whose output delivers the quantization noise of the primary ΣA-modulator in digitized format. Subsequently the output signals of the two ΣA-modulators are subtracted from each other so that the quantization noise of the primary ΣA-modulator is cancelled by the isolated quantization noise digitized by the secondary ΣA-modulator. The quantization noise originated in the secondary ΣA-modulator itself is not cancelled, but is of lower level.

However, the quantization noise in the output of the primary ΣA-modulator is filtered (shaped) with the inverse of the transfer function of the filtering means of this modulator. Therefore in the abovementioned article, the output signal of the secondary ΣA-modulator is filtered, in the digital domain, with a filter characteristic that is inverted to that of the (analog) filtering means of the primary ΣA-modulator. If the analog filter of the primary ΣA-modulator is realized in time discrete switched capacitor technology, then a reasonable match can be obtained between the filtering means of the primary ΣA-modulator and the inverse digital filter in the output of the secondary ΣA-modulator. However, if he analog filter is realized in time-continuous technology (e.g. gm-C technology) the component spread forces to apply additional tracking measures such as tuning of one of the filters to the other (as was done in the above mentioned paper on ISSCC2004).

The present invention has for its object to overcome this inconvenience and the AD-converter arrangement according to the invention is therefore characterized by filtering means in the feedback path of the secondary ΣA-modulator that have a transfer function which is, for the frequency band of the analog input signal, substantially equal to the transfer function of the open loop of the primary ΣA-modulator. When the feedback path of the primary ΣA-modulator does not have any filtering, then the open loop transfer function of this ΣA-modulator corresponds with the transfer function of its forward path and consequently the filtering in the feedback path of the secondary ΣA-modulator corresponds to the filtering in the forward path of the primary ΣA-modulator. On the other hand, when for any reason, e.g. for some filtering of the desired base band signals or for stability reasons, some filtering is included in the feedback path of the primary modulator or multiple feedback paths are provided to various points of the forward path of the primary modulator, then the transfer function of the feedback path of the secondary modulator has to be a substantial replica of the transfer function of the open loop of the primary modulator.

Preferably, to improve the tracking between the transfer functions of the open loop of the primary ΣA-modulator and the feedback path of the secondary ΣA-modulator the two transfer functions are realized in the same technology and with the same structure, e.g. both in time discrete switched capacitor technology or both in time-continuous gm-C technology. Further improvements of the matching between the two transfer functions may be obtained when the elements constituting these transfer functions have equal values. However because lower requirements with regard to dynamic range and S/N ratio have to be met by the secondary ΣA-modulator the impedances of the secondary modulator could be higher than those of the primary modulator, resulting in lower currents and smaller capacitances than those of the primary modulator and consequently in lesser chip area and lower power consumption.

The invention will be described with reference to the accompanying figures. Herein shows:

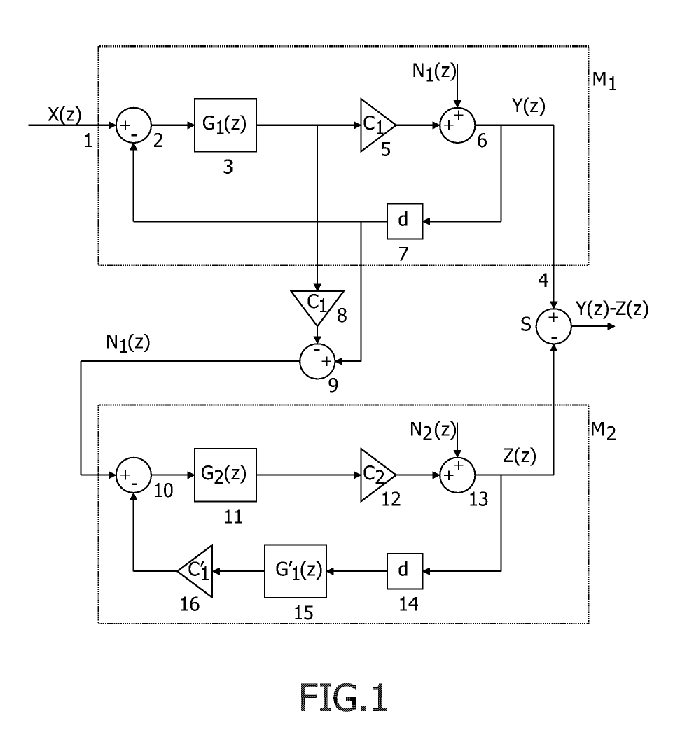

FIG. 1 a first embodiment of an AD converter arrangement according to the invention and

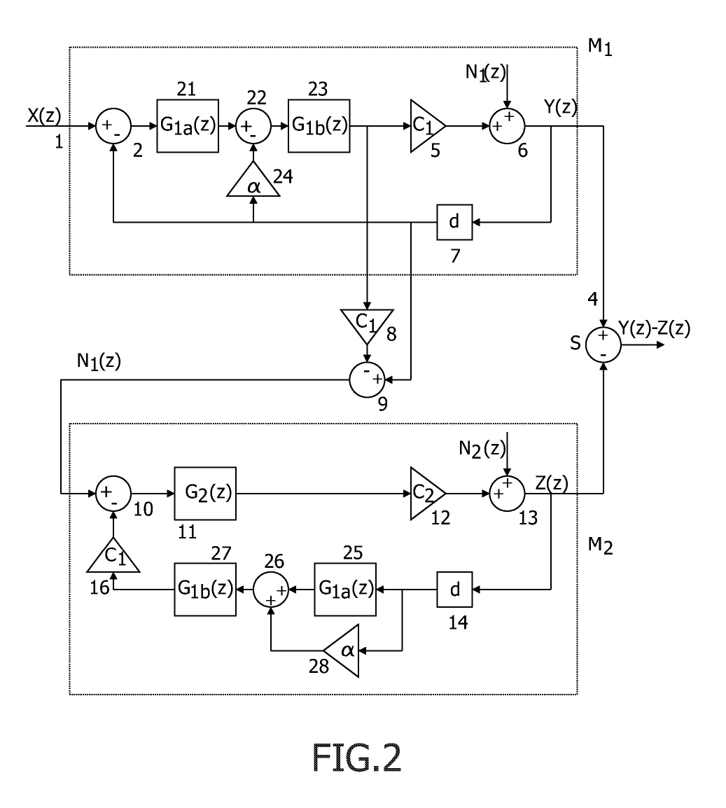

FIG. 2 a second embodiment of an AD converter arrangement according to the invention.

The AD converter arrangement of FIG. 1 comprises a standard primary ΣA-modulator M₁. This ΣA-modulator has an input terminal 1 for receiving an analog input signal X(z). This input signal may be a continuous time or a discrete time (sampled) analog signal. In this description the time discrete notation is followed. The input signal is fed through a subtraction point 2 to a filter 3 with transfer function G₁(z). The filter 3 is usually a low pass filter and serves the shaping of the quantization noise to higher frequencies, however the invention equally applies to other filter functions such as band-pass filtering means. The analog output signal of the filter 3 is applied to a quantizer that delivers a digital signal Y(z) to an output terminal 4 of the ΣA-modulator. In FIG. 1 the quantizer is represented by an amplifier 5 with amplification factor C₁ and an addition point 6 through which quantization noise N₁(z) is added to the signal. The base band frequency content of the digital signal Y(z) is equal to the input signal of the quantizer multiplied by the factor C₁ and anything else in the digital output signal Y(z) is the quantization noise N₁(z). Finally the digital output signal Y(z) of the quantizer is applied through a DA converter 7 to the minus input of the subtraction point 2 so that a closed loop configuration is obtained.

For this ΣA-modulator the following equation may be derived:

$$Y ( z ) = X ( z ) \cdot \frac{{C}_{1} {G}_{1} ( z )}{1 + {C}_{1} {G}_{1} ( z )} + \frac{{N}_{1} ( z )}{1 + {C}_{1} {G}_{1} ( z )} \qquad ( I )$$

When for the base band frequencies of X(z) the amplification C₁G₁(z) of the forward path of the ΣA-modulator is substantially larger then 1, this equation simplifies to

$$Y ( z ) \approx X ( z ) \cdot + \frac{{N}_{1} ( z )}{1 + {C}_{1} {G}_{1} ( z )} \qquad ( II )$$

Therefore, the input signal X(z) is preserved substantially without filtering in the digital output signal Y(z). In contradistinction therewith the quantization noise is decreased at the base band frequencies where the product C₁.G₁(z) is large and increases at higher frequencies where this product is small. With other words: the quantization noise is shaped to the higher frequencies above the base band.

The shaping of the quantization noise is more effective when the sample rate of the input signal X(z) is higher. However in practical transmission systems the sample rate of the signal is often limited. A different approach is to increase the order of the filter because a higher order filter gives a better noise shaping and therefore a better signal to noise ratio in the base band. A drawback of a higher order filter however is that the loop of the ΣA-modulator becomes potentially unstable for large signal excursions.

In the arrangement of FIG. 1 the transfer function G₁(z) of the filter 3 is chosen of a low filter order (typical first or second order) so that there is still a too high amount of quantization noise in the base band of the output signal Y(z). This is reduced in the following way: the quantization noise N₁(z) is isolated, the isolated quantization noise is digitized in a secondary ΣA-modulator M₂ and the so digitized quantization noise Z(z) is subtracted from the output signal Y(z) in a subtraction point S to obtain a signal Y(z)-Z(z) with reduced quantization noise.

The quantization noise N₁(z) is isolated in the analog domain by means of an amplifier 8 with amplification factor C₁ and a subtraction point 9. The amplifier 8 is needed because the interconnection between the amplifier 5 and the addition point 6 is not accessible in practice. It can easily be shown that the subtraction point 9 delivers the quantization noise N₁(z) without signal component, provided that the amplification of the amplifier 8 is equal to the base band amplification (C₁) of the quantizer (5,6) and provided that the amplification d of the DA converter 7 is unity. In case the DA converter provides some amplification or attenuation (d≠1) the amplification of the amplifier 8 has to be C₁.d.

The isolated noise N₁(z) is fed as input signal to a secondary ΣA-modulator M₂ in which the signal is applied through a subtraction point 10 and a low pass filter 11 with transfer function G₂(z) to a quantizer (12, 13). This quantizer is again represented by an amplifier 12 with amplification factor C₂ and an addition point 13 where quantization noise N₂(z) is added. The digital output signal Z(z) of the quantizer is fed back to the minus input of the subtraction point 10 through a feed-back path comprising in cascade an AD-converter 14, a filter 15 with transfer function G′₁(z) and an amplifier 16 with amplification C′₁. For this secondary ΣA-modulator the following equation applies:

$$Z ( z ) = \frac{{C}_{2} {G}_{2} ( z ) {N}_{1} ( z )}{1 + {C}_{1}^{′} {G}_{1}^{′} ( z ) {C}_{2} {G}_{2} ( z )} + \frac{{N}_{2} ( z )}{1 + {C}_{1}^{′} {G}_{1}^{′} ( z ) {C}_{2} {G}_{2} ( z )} \qquad ( III )$$

In case the loop gain of the secondary ΣA-modulator C′₁G′₁(z)C′₂G′₂(z) is substantially larger then 1 this equation simplifies to

$$Z ( z ) \approx \frac{{N}_{1} ( z )}{{C}_{1}^{′} {G}_{1}^{′} ( z )} + \frac{{N}_{2} ( z )}{1 + {C}_{1}^{′} {G}_{1}^{′} ( z ) {C}_{2} {G}_{2} ( z )} \qquad ( IV )$$

It is noted that, when the transfer function G′₁(z) of the filter 15 is (substantially) equal to the transfer function G₁(z) of the filter 3 and the two amplification factors C₁(z) and C₁′(z) are also equal, the term for N₁(z) in this equation (IV) is the same as the term for N₁(z) in equation (II) for the output signal Y(z) of the primary ΣA-modulator. Then the output signal Y(z)-Z(z) of the subtraction point S is equal to:

$$Y ( z ) - Z ( z ) = X ( z ) - \frac{{N}_{2} ( z )}{1 + {C}_{1}^{′} {G}_{1}^{′} ( z ) {C}_{2} {G}_{2} ( z )} \qquad ( V )$$

This result is obtained with a filter 15 in the feedback path of the secondary ΣA-modulator that has the same transfer function as the filter 3 in the forward path of the primary ΣA-modulator. Moreover the two filters are both in the analog domain and therefore may be implemented in the same technology. The two filters 3 and 15 can therefore be made with perfect matching with the result that optimal suppression of the N₁(z) noise in the output of the arrangement can be obtained. This in contrast to the prior art arrangement of the above mentioned article in which the filtering of the quantization noise N₁(z) is realized by a filter in the output lead of the secondary ΣA-modulator. The transfer function of this filter should be inverse to the filter G₁(z) of the primary ΣA-modulator and has to be implemented in the digital domain. The stability in the secondary ΣA-modulator is better controlled as this ΣA-modulator sees less strong excursions then the primary ΣA-modulator. Moreover any malfunction of the secondary ΣA-modulator can be suppressed with limiters thereby only slightly reducing the overall performance, as the primary ΣA-modulator will continue to work correctly.

In the above explanation of the operation of the arrangement of FIG. 1 it has been assumed that the two DA-converters 7 and 14 have no amplification or attenuation (d=1). A further analysis of the arrangement of the invention shows that for optimum suppression of the N₁(z) noise the transfer function of the feedback path of the secondary ΣA-modulator M₂ should be equal to the open loop transfer function of the primary ΣA-modulator M₁. In the arrangement of FIG. 1 the open loop transfer function of the modulator M₁ is d.G₁(z).C₁ whereas he transfer function of the feedback path of the modulator M₂ is also d.G₁(z).C₁. Therefore the amplification factors d of the two DA converters need not to be unity, but for optimum noise suppression they have to be equal. It is also noted that usually a digital delay of some sample-periods (not shown in the figure) is included in the output lead (4) of the primary ΣA-modulator to cope with the intrinsic delay of the secondary ΣA-modulator.

It is apparent from equation (IV) that the output signal Y(z)-Z(z) of the arrangement still has in band quantization noise N₂(z) originating from the secondary ΣA-modulator M₂. However this noise is shaped by both filters G₁(z) and G₂(z). Therefore, when each of these filters is a 2^{nd} order filter, the noise N₂(z) is effectively shaped by a 4^{th} order filter, without the stability of the primary ΣA-modulator being endangered.

As stated above the transfer function of the feedback path of the secondary ΣA-modulator M₂ has to correspond with the open loop transfer function of the primary ΣA-modulator M₁. This also holds for a ΣA-modulator with more complicated filter structures then the single filter G₁(z). This is illustrated in FIG. 2 in which elements that correspond with those of FIG. 1 have been given the same reference numerals. Instead of the single filter 3 in the primary ΣA-modulator of FIG. 1 the primary ΣA-modulator of FIG. 2 contains a filter 21 with transfer function G₁ₐ(Z), a subtraction point 22 and a second filter 23 with transfer function G_{1b}(z) in cascade. The output signal Y(z) is, after DA conversion in the DA converter 7, applied directly to the minus input of subtraction point 2 and, through a scaler 24 with scaling factor α, to the minus input of subtraction point 22. ΣA-modulators with such more complicated filter structures are well known in the art, see for instance applicants' prior patent application (PHNL 030766). The open loop transfer function of this ΣA-modulator, i.e. the transfer function from for instance the output of addition point 6 through the elements 7, 2, 21, 22, 23, 24 and 5 to the input of addition point 6, is equal to d.{G₁ₐ(z)+α}.G_{1b}.C₁.

To obtain optimal suppression of the quantization noise N₁(z) in the output signal of the arrangement, the feedback path of the secondary ΣA-modulator M₂ should have the same transfer function. This is implemented in FIG. 2 by the cascade of the DA converter 14, a filter 25 with transfer function G₁ₐ(Z), an addition point 26, a filter 27 with transfer function G_{1b}(z) and the amplifier 16. Moreover the output of the DA converter 14 is applied through a scaler 28 with scaling factor α to the addition point 26. These six elements together constitute a path with transfer function d.{G₁ₐ(z)+α}.G_{1b}.C₁ i.e. the same as the open loop transfer of the modulator M₁. The elements may be identical in implementation to the corresponding elements of the primary ΣA-modulator so that optimum filter matching is obtained.

1. AD converter arrangement comprising a primary (M₁) and a secondary (M₂) ΣA-modulator each with an input terminal for receiving an analog input signal, filtering means in a forward path between said input terminal and a quantizer, an output terminal connected to the output of the quantizer and a feedback path connected from the output of the quantizer to the filtering means, the AD converter arrangement further comprising means (1) to apply an analog input signal to the input terminal of the primary ΣA-modulator, means (7,8) to isolate the quantization noise N₁(z) generated in the primary ΣA-modulator, means to apply said isolated quantization noise to the input terminal of the secondary ΣA-modulator and means (S) to derive a combination of the digital output signals of the two ΣA-modulators so as to substantially reduce the quantization noise of the primary ΣA-modulator in said combination characterized by filtering means (14, 15, 16) in the feedback path of the secondary ΣA-modulator that have a transfer function which is, for the frequency band of the analog input signal, substantially equal to the transfer function of the open loop of the primary ΣA-modulator.

2. Arrangement as claimed in claim 1 characterized in that the transfer function of the open loop of the primary ΣA-modulator and of the feedback path of the secondary ΣA-modulator are implemented in the same technology and with the same structure.

3. Arrangement as claimed in claim 2 characterized in that the impedance level of elements of the feedback path of the secondary modulator is higher than that of the corresponding elements of the feedback path and the forward path of the primary modulator.
